(19) United States
(12) Patent Application Publication
(10) Pub. No.: US 2022/0317582 A1
(43) Pub. Date: Oct. 6, 2022

(54) WAFER EDGE EXPOSURE METHOD, WAFER EDGE EXPOSURE DEVICE AND MASK

(71) Applicant: CHANGXIN MEMORY TECHNOLOGIES, INC., Hefei City, Anhui (CN)

(72) Inventor: CHI-NAN CHEN, Hefei (CN)

(73) Assignee: CHANGXIN MEMORY TECHNOLOGIES, INC., Hefei City, Anhui (CN)

(21) Appl. No.: 17/310,764

(22) PCT Filed: Mar. 23, 2021
(86) PCT No.: PCT/CN2021/082446

§ 371 Date: Aug. 21, 2021

(30) Foreign Application Priority Data
Mar. 23, 2020 (CN) 202010206803.8

(51) Int. Cl. G03F 9/00; G03F 1/54

(52) U.S. Cl. CPC G03F 9/7073; G03F 1/54

(57) ABSTRACT

A wafer edge exposure method includes: providing a wafer, the edge of the wafer having multiple regions to be exposed and non-exposed regions adjacent to the plurality of regions to be exposed; and providing a wafer edge exposure device, aligning in sequence the wafer edge exposure device with each of the regions to be exposed while isolating from the non-exposed regions, and exposing each of the regions to be exposed. The wafer edge exposure method, the wafer edge exposure device, and the mask can reduce the damage to effective wafers during the exposure process while ensuring the exposure effect of the wafers.

### CROSS-REFERENCE TO RELATED APPLICATIONS

The present disclosure claims priority to Chinese Patent Application No. 202010206803.8, entitled “Wafer edge exposure method, wafer edge exposure device and mask”, filed on Mar. 23, 2020, which is incorporated herein by reference in its entirety.

### TECHNICAL FIELD

The present disclosure relates to the field of semiconductor manufacturing, and in particular, to a wafer edge exposure method, a wafer edge exposure device and a mask.

### BACKGROUND

Wafers refer to silicon dies used in the production of silicon semiconductor integrated circuits. Because of their circular shape, they are called wafers. Various circuit element structures can be processed on silicon dies to become IC products with specific electrical functions. The raw material of the wafers is silicon, and there is inexhaustible silicon dioxide on the earth's crust surface. The silica ores are refined by electric arc furnaces, chlorinated with hydrochloric acid, and then distilled to produce high-purity polycrystalline silicon. However, the traditional wafer production processes vary greatly in level, and are generally complicated in operation, high in cost and low in yield. In the prior art, in order to avoid defects at the crystal edge of the wafers, the crystal edge is exposed.

However, the wafer edge exposure methods in the prior art will cause the damage to some of effective dies at the wafer edge and thus affect the quality of the wafer.

### SUMMARY

The purpose of the embodiments of the present disclosure is to provide wafer edge exposure method, wafer edge exposure device and mask, which can reduce the damage to the wafer during the exposure process while ensuring the exposure effect of the dies.

In order to solve the technical problem, an embodiment of the present disclosure provides a wafer edge exposure method, comprising: providing a wafer, the edge of the wafer having multiple regions to be exposed and non-exposed regions adjacent to the plurality of regions to be exposed; and providing a wafer edge exposure device, aligning in sequence the wafer edge exposure device with each of the regions to be exposed while isolating from the non-exposed regions, and exposing each of the regions to be exposed.

An embodiment of the present disclosure further provides a wafer edge exposure device, comprising: a wafer rotating component, a control component and an exposure component; the control component controls the wafer rotating component to rotate by a preset angle in sequence; and when the wafer rotating component rotates to the preset angle, the control component controls the exposure component to adjust the exposure area and the exposure time.

An embodiment of the present disclosure further provides a mask, comprising: a main body provided with a light-transmitting hole; and light-shielding plates movably arranged on the main body, the light-shielding plates being used to shield at least a part of the light-transmitting hole to adjust the area of the light-transmitting hole.

Compared with the prior art, in the embodiment of the present disclosure, the edge of a wafer is divided into regions to be exposed and non-exposed regions. When each of the regions to be exposed is exposed by the wafer edge exposure device, the wafer edge exposure device is aligned in sequence with each of the regions to be exposed to expose each of the regions to be exposed. In this way, the exposure effect is effectively ensured. In addition, since the wafer edge exposure device is aligned in sequence with each of the regions to be exposed while being isolated from the non-exposed regions, this effectively ensures that the non-exposed regions will not be exposed and thus reduces the damage to the wafer during the exposure process.

In addition, the aligning in sequence the wafer edge exposure device with each of the regions to be exposed comprises: setting an alignment mark on each of the regions to be exposed; and rotating the wafer so that the wafer edge exposure device is aligned with the alignment marks in sequence.

In addition, the rotating the wafer so that the wafer edge exposure device is aligned with the alignment marks in sequence comprises: determining the initial position of the wafer by notch alignment for the wafer; calculating a central angle between each of the alignment marks and the initial position of the wafer according to the position information of each of the regions to be exposed; and rotating the wafer in sequence according to the central angle, so that the wafer edge exposure device is aligned with the alignment marks in sequence.

In addition, the wafer edge exposure method further comprises: controlling the wafer edge exposure device to change the exposure area and the exposure time according to the position information of each of the regions to be exposed.

In addition, the wafer edge exposure device comprises a mask, the mask comprising a light-transmitting hole for exposure and light-shielding plates for shielding the light-transmitting hole; and the controlling the wafer edge exposure device to change the exposure area comprises: changing the position of the light-shielding plates to adjust the area of the light-transmitting hole shielded by the light-shielding plates.

In addition, the exposure component comprises a mask, the mask comprising a light-transmitting hole for exposure and light-shielding plates for shielding the light-transmitting hole; and the adjusting the exposure area specifically comprises: changing the position of the light-shielding plates to adjust the area of the light-transmitting hole shielded by the light-shielding plates.

In addition, the wafer edge exposure device further comprises power devices connected to the light-shielding plates, the power devices being used to drive the light-shielding plates to move.

In addition, there are multiple light-shielding plates; and the multiple light-shielding plates at least comprise two light-shielding plates that are perpendicular to each other, and/or the multiple light-shielding plates at least comprise two light-shielding plates that are parallel to each other.

### BRIEF DESCRIPTION OF THE DRAWINGS

One or more embodiments will be exemplified by pictures in the corresponding drawings. These exemplified descriptions do not constitute any limitation to the embodiments. Elements with the same reference numerals in the drawings are represented as similar. Unless otherwise stated, the drawings are not necessarily drawn to scale.

FIG. 1 is a flowchart of a wafer edge exposure method according to an embodiment of the present disclosure;

FIG. 2 is a schematic structure diagram of a wafer in a wafer edge exposure method according to an embodiment of the present disclosure;

FIG. 3 is a flowchart of exposing regions to be exposed in a wafer edge exposure method according to an embodiment of the present disclosure;

FIG. 4 is a schematic structure diagram of exposing regions to be exposed in a wafer edge exposure method according to an embodiment of the present disclosure;

FIG. 5 is a schematic structure diagram of a mask according to another embodiment of the present disclosure;

FIG. 6 is a schematic structure diagram of a mask according to still another embodiment of the present disclosure; and

FIG. 7 is a schematic structure diagram of a wafer edge exposure device according to yet another embodiment of the present disclosure.

### DETAILED DESCRIPTION

To make the objectives, technical solutions and advantages of the present disclosure clearer, some embodiments of the present disclosure will be described below in detail with reference to the accompanying drawings. However, it may be understood by a person of ordinary skill in the art that, in the embodiments of the present disclosure, many technical details are provided for the better understanding of the present disclosure. However, the technical solutions sought to be protected by the present disclosure can be implemented, even without these technical details and various changes and modifications based on the following embodiments.

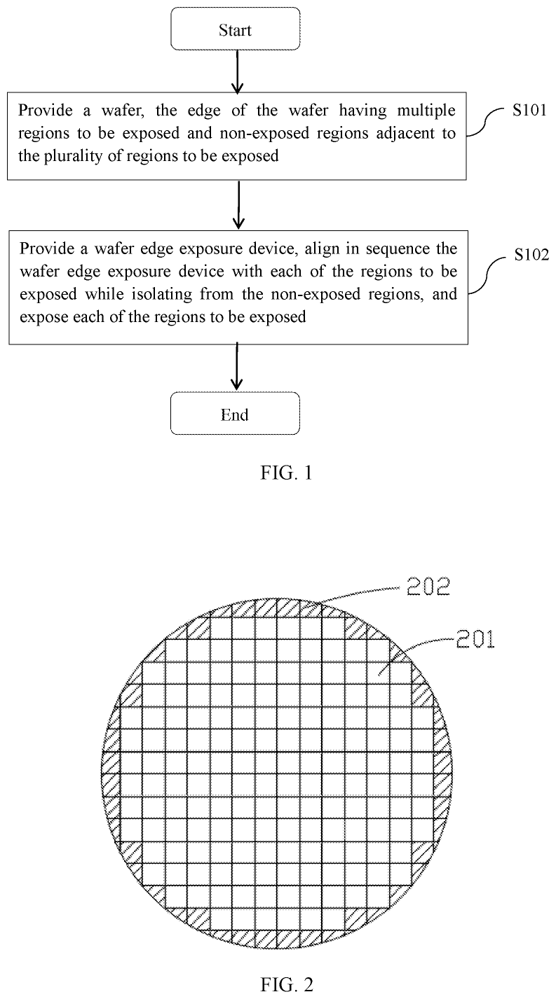

An embodiment of the present disclosure relates to a wafer edge exposure method. The specific flow is shown in FIG. 1. The wafer edge exposure method comprises the following steps.

S101: A wafer is provided, the edge of the wafer having multiple regions to be exposed and non-exposed regions adjacent to the plurality of regions to be exposed.

In an embodiment, as shown in FIG. 2, multiple dies are arranged on the wafer. The positions of the dies that are located at the edge of the wafer and do not need to be exposed are obtained. The regions of the dies that do not need to be exposed are considered as the non-exposed regions 201. The non-exposed regions 201 divide the edge of the wafer into multiple regions to be exposed 202.

S102: A wafer edge exposure device is provided, the wafer edge exposure device is aligned in sequence with each of the regions to be exposed while isolating from the non-exposed regions, and each of the regions to be exposed is exposed.

In an embodiment, alignment marks are set in the regions to be exposed 202 in advance, and then the wafer is rotated so that the wafer edge exposure device obtains the alignment marks in sequence and aligns with the alignment marks, thereby aligning with the regions to be exposed. It may be understood that the rotation of the wafer to enable the wafer edge exposure device to obtain the alignment marks in sequence is just a specific example in this embodiment and does not constitute any limitation. In other embodiments of the present disclosure, possibly, the wafer edge exposure device is rotated so that the wafer edge exposure device obtains the alignment marks in sequence; or both the wafer and the wafer edge exposure device are rotated; and so on, which will not be listed here and may be flexibly determined according to actual needs.

In an embodiment, the central angle between each alignment mark and the initial position of the wafer is calculated in advance. When exposing the edge of the wafer, the initial position of the wafer is first determined, that is, the wafer edge exposure device is aligned with the initial position of the wafer by methods such as notch alignment and zeroing. Then, the wafer and/or wafer edge exposure device is rotated. According to the central angle calculated in advance, every time it is rotated by the central angle calculated in advance, the wafer edge exposure device is aligned with an region to be exposed. Thus, the wafer edge exposure device is aligned with the regions to be exposed in sequence.

In an embodiment, since the area and exposure time of the regions to be exposed are different, a corresponding relationship between the area of each region to be exposed and its position and exposure time is established in advance. When exposing the edge of the wafer, each time the wafer edge exposure device is aligned with a region to be exposed, the corresponding exposure area and exposure time are obtained according to the position of the region to be exposed. The wafer edge exposure device is controlled to change the exposure area and exposure time according to the region to be exposed.

In an embodiment, the wafer edge exposure device comprises a mask, and a movable light-shielding plate is provided in the mask. By adjusting the position of the light-shielding plates, the area of the light-transmitting hole shielded by the light-shielding plates may be adjusted, so as to adjust the shape and area of the light-transmitting hole. By adjusting the position of the light-shielding plates, the area of the light-transmitting hole may be adjusted, so that different regions to be exposed can be exposed by one mask. The exposure requirements of the regions to be exposed may be met without requiring multiple masks, which effectively simplifies the exposure process.

In an embodiment, by power devices provided on the mask, the light-shielding plates are driven to move in order to change the position of the light-shielding plates. In this way, the shape and area of the light-transmitting hole are adjusted. By driving the light-shielding plates to move by the power devices provided on the mask, the position of the light-shielding plates can be set more accurately, the accuracy of the light-transmitting hole can be improved, and the damage to the effective dies during the exposure process can be further reduced.

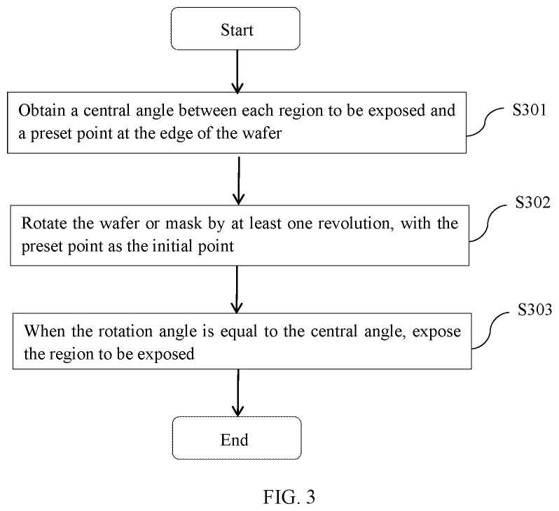

In an embodiment, FIG. 3 shows a specific embodiment of exposing regions to be exposed 202 in this embodiment. It may be ensured that the regions to be exposed 202 can be all exposed, without any omission. It may be understood that what shown in FIG. 3 is just a specific example in this embodiment and does not constitute any limitation. In other embodiments of the present disclosure, other methods may be used and will not be listed here. The method specifically comprises the following steps.

S301: A central angle between each region to be exposed and a preset point at the edge of the wafer is obtained.

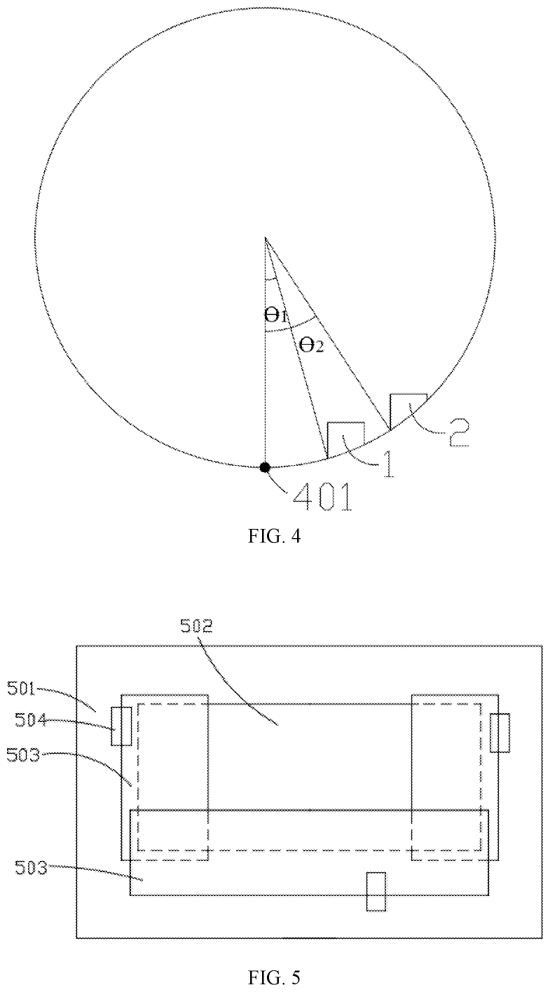

In an embodiment, as shown in FIG. 4, a central angle between a sampling point randomly selected in each region to be exposed (for example a corner of a region to be exposed) and a preset point 401 may be obtained, as the central angle between the region to be exposed and the preset point.

S302: The wafer or mask is rotated by at least one revolution, with the preset point as the initial point.

In an embodiment, the wafer and the mask are rotated by one revolution relative to each other. In the specific embodiment process, the wafer may be rotated by one revolution or the mask may be rotated by one revolution, which may be flexibly determined according to actual needs.

Step S303: When the rotation angle is equal to the central angle, the region to be exposed is exposed.

In an embodiment, when the rotation angle is equal to the central angle. As shown in FIG. 4, the central angle of the region to be exposed No. 1 is θ1, and the central angle of the region to be exposed No. 2 is θ2. When the rotation angle is θ1, the region to be exposed No. 1 may be exposed. When the rotation angle is θ2, the region to be exposed No. 2 may be exposed.

Compared with the prior art, in the wafer edge exposure method in an embodiment of the present disclosure, the wafer edge is divided, according to the effective dies, into multiple regions to be exposed; when the wafer or mask is rotated to expose the regions to be exposed one by one, by adjusting the shape and area of the light-transmitting hole so that the orthographic projection of the light-transmitting hole on the wafer is isolated from the effective dies, the damage to the effective dies during the exposure process is reduced; in addition, since the orthographic projection of the light-transmitting hole on the wafer covers the region that is currently exposed, the effective exposure of the edge of the wafer and thus the exposure effect of the wafer can be ensured.

The division of the steps of the various methods above is just for clarity of description. When implemented, the steps may be combined into one step or some steps may be split and decomposed into multiple steps, as long as they include the same logical relationship, without departing from the scope of the present disclosure. Adding insignificant modifications to the algorithm or process or introducing insignificant designs without changing the key design of the algorithm or process are within the protection scope of the present disclosure.

Another embodiment of the present disclosure relates to a mask, as shown in FIG. 5, comprising: a main body 501 provided with a light-transmitting hole 502, and light-shielding plates 503 movably arranged on the main body 501, the light-shielding plates 503 being used to shield at least a part of the light-transmitting hole 502 to adjust the area of the light-transmitting hole 502.

Compared with the prior art, the mask according another embodiment of the present disclosure is provided with a movable light-shielding plate 503, and the size and position of the light-transmitting hole 502 may be adjusted by adjusting the position of the light-shielding plates 503 so that a variety of different exposure requirements may be met by one mask.

In an embodiment, the mask further comprises: power devices 504 connected to the light-shielding plates 503, the power devices 504 being used to drive the light-shielding plates 503 to move. By driving the light-shielding plates 503 to move by the power devices 504, the movement distance of the light-shielding plates 503 can be effectively controlled and the accuracy of the position of the light-shielding plates 503 can be ensured.

In an embodiment, there are multiple light-shielding plates 503; and the multiple light-shielding plates 503 at least comprise two light-shielding plates 503 that are perpendicular to each other, and/or the multiple light-shielding plates 503 at least comprise two light-shielding plates 503 that are parallel to each other. With the arrangement of the two light-shielding plates 503 that are perpendicular and/or parallel to each other, the area and position of the light-transmitting hole 502 can be further controlled.

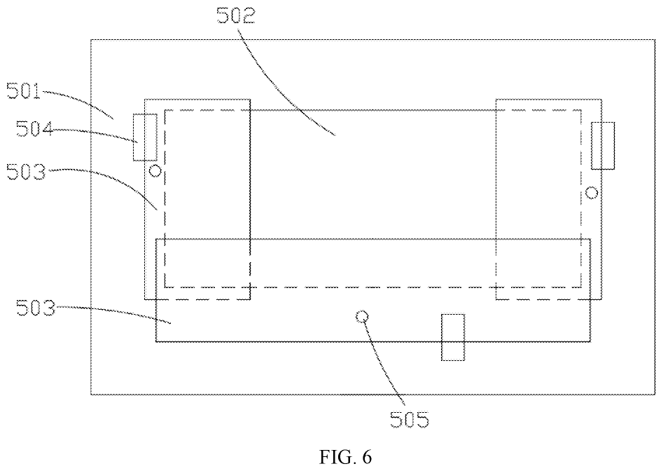

Still another embodiment of the present disclosure relates to a mask. As shown in FIG. 6, this mask also comprises a main body 501, a light-transmitting hole 502, light-shielding plates 503, and power devices 504. The main difference lies in that, in the second embodiment of the present disclosure, the mask further comprises a rotating shaft 505 arranged on the light-shielding plates 503.

In an embodiment, the light-shielding plates 503 can be rotated around the rotating shaft 505, in addition to its movable arrangement on the main body 501 as described in the second embodiment.

Compared with the prior art, the mask according to still another embodiment of the present disclosure retains all the technical effects of the foregoing embodiments, and meanwhile, by providing a rotating shaft 505, the light-shielding plates 503 can be rotated around the rotating shaft 505, which further improves the adjustability of the shape and position of the light-transmitting hole 502.

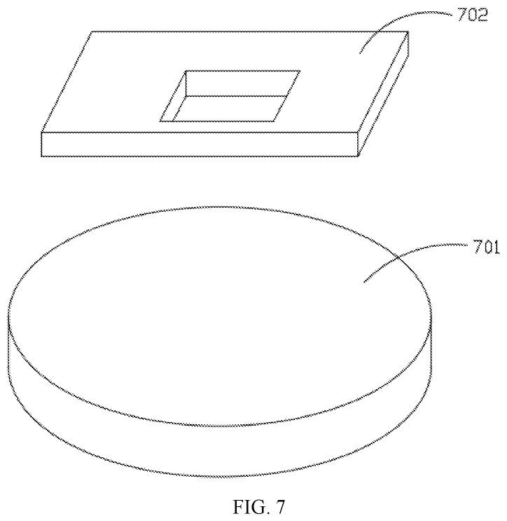

Yet another embodiment of the present disclosure relates to a wafer edge exposure device, as shown in FIG. 7, comprising a wafer rotating component 701, a control component (not shown), and an exposure component 702. The control component controls the wafer rotating component 701 to rotate by a preset angle in sequence. When the wafer rotating component 701 rotates to the preset angle, the control component controls the exposure component 701 to adjust the exposure area and the exposure time, to expose the regions to be exposed. The exposure component 702 comprises the mask according to other embodiments of the present disclosure.

Compared with the prior art, the mask in the wafer edge exposure device in yet another embodiment of the present disclosure is a mask in other embodiments of the present disclosure, so that the area of the light-transmitting hole can be adjusted. After a region to be exposed is obtained, the area of the light-transmitting hole of the mask in the exposure component 702 may be adjusted to expose the region to be exposed.

In an embodiment, the wafer rotating component 701 and the exposure component 702 can rotate relative to each other, and the wafer rotating component 701 can drive the wafer to rotate synchronously. It may be understood that, in this embodiment, the wafer rotating component 701 may be set to rotate, or the exposure component 702 may be set to rotate, which may be flexibly determined according to actual needs. By setting the wafer rotating component 701 and the exposure component 702 to rotate relative to each other, the wafer edge exposure method in the first embodiment of the present disclosure can be executed. Details may be found in the specific description of the first embodiment and will not be repeated here.

It may be understood by a person of ordinary skill in the art that the above-mentioned embodiments are specific embodiments for realizing the present disclosure, and in actual disclosures, various changes may be made to the form and details without departing from the spirit and scope of the present disclosure.

What is claimed is:

1. A wafer edge exposure method, comprising:
providing a wafer, an edge of the wafer having multiple regions to be exposed and non-exposed regions adjacent to the plurality of regions to be exposed; and
providing a wafer edge exposure device, aligning in sequence the wafer edge exposure device with each of the regions to be exposed while isolating from the non-exposed regions, and exposing each of the regions to be exposed.

2. The method according to claim 1, wherein the aligning in sequence the wafer edge exposure device with each of the regions to be exposed comprises:
setting an alignment mark on each of the regions to be exposed; and
rotating the wafer so that the wafer edge exposure device is aligned with the alignment marks in sequence.

3. The method according to claim 2, wherein the rotating the wafer so that the wafer edge exposure device is aligned with the alignment marks in sequence comprises:
determining the initial position of the wafer by notch alignment for the wafer;
calculating a central angle between each of the alignment marks and the initial position of the wafer according to the position information of each of the regions to be exposed; and
rotating the wafer in sequence according to the central angle, so that the wafer edge exposure device is aligned with the alignment marks in sequence.

4. The method according to claim 2, further comprising: controlling the wafer edge exposure device to change the exposure area and the exposure time according to the position information of each of the regions to be exposed.

5. The method according to claim 4, wherein the wafer edge exposure device comprises a mask, the mask comprising a light-transmitting hole for exposure and light-shielding plates for shielding the light-transmitting hole;
the controlling the wafer edge exposure device to change the exposure area comprises:
changing the position of the light-shielding plates to adjust the area of the light-transmitting hole shielded by the light-shielding plates.

6. A wafer edge exposure device, comprising:
a wafer rotating component, a control component and an exposure component;
the control component controls the wafer rotating component to rotate by a preset angle in sequence; and
when the wafer rotating component rotates to the preset angle, the control component controls the exposure component to adjust the exposure area and the exposure time.

7. The device according to claim 6, wherein the exposure component comprises a mask, the mask comprising a light-transmitting hole for exposure and light-shielding plates for shielding the light-transmitting hole;
the adjusting the exposure area specifically comprises:
changing the position of the light-shielding plates to adjust the area of the light-transmitting hole shielded by the light-shielding plates.

8. A mask, comprising:
a main body provided with a light-transmitting hole; and
light-shielding plates movably arranged on the main body, the light-shielding plates being used to shield at least a part of the light-transmitting hole to adjust the area of the light-transmitting hole.

9. The mask according to claim 8, further comprising: power devices connected to the light-shielding plates, the power devices being used to drive the light-shielding plates to move.

10. The mask according to claim 8, wherein there are multiple light-shielding plates; and
the multiple light-shielding plates at least comprise two light-shielding plates that are perpendicular to each other, and/or the multiple light-shielding plates at least comprise two light-shielding plates that are parallel to each other.
